(19) United States
(12) Patent Application Publication
(10) Pub. No.: US 2002/0113649 A1
(43) Pub. Date: Aug. 22, 2002

(54) Long subscriber loops using modified load coils

(76) Inventors: Atul Anil Tambe, Cupertino, CA (US); Kishan Shenoi, Saratoga, CA (US); Gary Bogardus, San Carlos, CA (US)

Correspondence Address: FULBRIGHT & JAWORSKI L.L.P., REGISTERED LIMITED LIABILITY PARTNERSHIP, SUITE 2400, 600 CONGRESS AVENUE, AUSTIN, TX, 78701, US

(21) Appl. No.: 09/836,889

(22) Filed: Apr. 16, 2001

Related U.S. Application Data
(60) Provisional application No. 60/197,993, filed on Apr. 18, 2000.

(51) Int. Cl. H03F 3/04

(52) U.S. Cl. 330/250

(57) ABSTRACT

Systems and methods are described for long subscriber loops using modified load coils. A method includes providing a circuit to extend a transmission medium, the circuit including an inductor and a shunt network, the inductor including a first leg and a second leg, the shunt network including a first circuit portion and a second circuit portion, the first circuit portion including a first capacitor and a first resistor, the first capacitor disposed in a parallel relationship across the first leg of the inductor, the first resistor disposed in a parallel relationship across the first leg of the inductor, the second circuit portion including a second capacitor and a second resistor, the second capacitor disposed in a parallel relationship across the second leg of the inductor, the second resistor disposed in a parallel relationship across the second leg of the inductor; providing an inductive admittance from the first leg of the inductor to a first communication transmitted within a first frequency band; and providing a capacitive admittance from the first circuit portion of the shunt network to a second communication transmitted within a second frequency band. An apparatus includes a circuit including an inductor and a shunt network, the inductor having a first leg and a second leg, the shunt network including a first circuit portion and a second circuit portion, the first circuit portion including a first capacitor and a first resistor, the first capacitor disposed in a parallel relationship across the first leg of the inductor, the first resistor disposed in a parallel relationship across the first leg of the inductor, and the second circuit portion including a second capacitor and a second resistor, the second capacitor disposed in a parallel relationship across the second leg of the inductor, the second resistor disposed in a parallel relationship across the second leg of the inductor, the first leg of the inductor provides an inductive admittance to a first communication transmitted within a first frequency band, and the first circuit portion of the shunt network provides a capacitive admittance to a second communication transmitted within a second frequency band.

### CROSS-REFERENCE TO RELATED APPLICATION

This application is related to, and claims a benefit of priority under 35 U.S.C. 119(e) and/or 35 U.S.C. 120 of copending U.S. Ser. No. 60/197,993, filed Apr. 18, 2000, now pending, the entire contents of which are hereby incorporated by reference for all purposes.

### BACKGROUND OF THE INVENTION

1. Field of the Invention

The invention relates generally to the field of communications. More particularly, the invention relates to digital subscriber loop (DSL) communications. Specifically, a preferred implementation of the invention relates to extending the range of an asymmetric digital subscriber loop (ADSL). The invention thus relates to ADSL of the type that can be termed extended.

2. Discussion of the Related Art

Conventional telephony, often called plain old telephone service (POTS), is provided to customers over copper cable. This copper cable can be termed a subscriber loop or a subscriber line. Modern loop plant designs specify the use of 26-gauge cable for short to medium loop lengths with 24-gauge cable used to extend the range. Legacy loop plant includes cable of 22-gauge as well as 19-gauge.

At the customer premises, a telephone set is typically connected to the cable. The other end of the cable is connected to a line circuit module in the service provider's central office (CO). Switches terminating customer loops at the central office are regarded as Class-5 switches and provide a dial-tone. The customer premise equipment (CPE) can include a personal computer (PC) modem.

Older central office switches were analog in nature and were unable to provide a broad range of services. Modern central office switches are digital. Digital switches include codecs in the line circuit to do the bilateral analog-digital (A/D) conversion; the transmission over the loop is analog and the signals occupy a frequency band of up to (approximately) 4 kHz. Conventional telephony codecs convert at an 8 kHz sampling rate and quantize to 8 bits per sample corresponding to a net bit rate of 64 kbps (or “DS0”).

With the advent of digital terminal equipment, such as personal computers, modems were developed to carry digital bit streams in an analog format over the cable pair. Because of the 4 kHz constraint imposed by the A/D converter in the line circuit, the data rate of such transmission is limited and is typically 9.6 kbps. More elaborate schemes have been proposed which permit higher bit rates (e.g. V.34 which can do in excess of 28.8 kbps). More recently, there are schemes that “spoof” the D/A converter in the line-circuit operate at bit rates as high as 56 kbps in the downstream direction (from CO to CPE). With increasing deployment of, and consequently demand for, digital services it is clear that this bit rate is insufficient.

An early proposal to increase the information carrying capacity of the subscriber loop was ISDN (“Integrated Services Digital Network”), specifically the BRI (“Basic Rate Interface”) which specified a “2B+D” approach where 2 bearer channels and one data channel (hence 2B+D) were transported between the CO and the CPE. Each B channel corresponded to 64 kbps and the D channel carried 16 kbps. With 16 kbps overhead, the loop would have to transport 160 kbps in a full duplex fashion. This was the first notion of a Digital Subscriber Loop (“DSL”) (or Digital Subscriber Line). However, this approach presumed that POTS and 2B+D would not coexist (simultaneously). The voice codec would be in the CPE equipment and the “network” would be “all-digital”. Most equipment was designed with a “fall-back” whereby the POTS line-circuit would be in a “stand-by” mode and in the event of a problem such as a power failure in the CPE, the handset would be connected to the loop and the conventional line-circuit would take over. There are several ISDN DSLs operational today.⁽¹⁻²⁾

Asymmetric digital subscriber loop (ADSL) was proposed to provide a much higher data rate to the customer in a manner that coexisted with POTS. Recognizing that the spectral occupancy of POTS is limited to low frequencies, the higher frequencies could be used to carry data (the so-called Data over Voice approach). Nominally, ADSL proposed that 10 kHz and below would be allocated to POTS and the frequencies above 10 kHz for data. Whereas the nominal ADSL band is above 10 kHz, the latest version of the standard specifies that the “useable” frequency range is above 20 kHz. This wide band between 4 kHz and the low edge of the ADSL band simplifies the design of the filters used to segregate the bands.

Furthermore, it was recognized that the downstream data rate requirement is usually much greater than the upstream data rate requirement. Several flavors (“Classes”) of ADSL have been standardized, involving different data rates in the two directions. The simplest is Class-4 which provides (North American Standard) 1.536 Mbps in the downstream direction and 160 kbps in the upstream direction. The most complicated, Class-1, provides about 7 Mbps downstream and 700 kbps upstream.⁽³⁻⁴⁾

A stumbling block in specifying, or guaranteeing, a definite bit rate to a customer is the nature of the loop plant. Customers can be at varied geographical distances from the central office and thus the length of the subscriber loop is variable, ranging from short (hundreds of feet) to long (thousands of feet) to very long (tens of thousands of feet). The essentially lowpass frequency response of subscriber cable limits the usable bandwidth and hence the bit rate.

Moreover, loops longer than (approximately) 18 thousand feet have a lowpass characteristic that even affects the voiceband. Such loops are specially treated by the addition of load coils and are called “loaded loops”. The principle is to splice in series-inductors which have the impact of “boosting” the frequency response at (approximately) 4 kHz with the secondary effect of increasing the attenuation beyond 4 kHz very substantially. In these loaded loops, the spectral region above 10 kHz is unusable for reliable transmission. Consequently, the categorical statement can be made that DSL (including ADSL, “2B+D”, and other flavors of DSL) cannot be provided over long loops and definitely cannot be provided over loaded loops.

Heretofore, there has not been a completely satisfactory approach to providing DSL over long loops. Further, there has not been a satisfactory approach to providing DSL over loaded loops. What is needed is a solution that addresses one, or both, of these requirements. The invention is directed to meeting these requirements, among others.

### SUMMARY OF THE INVENTION

There is a need for the following embodiments. Of course, the invention is not limited to these embodiments.

One embodiment of the invention is based on a method, comprising: providing a circuit to extend a transmission medium, said circuit including an inductor and a shunt network, said inductor including a first leg and a second leg, said shunt network including a first circuit portion and a second circuit portion, said first circuit portion including a first capacitor and a first resistor, said first capacitor disposed in a parallel relationship across said first leg of said inductor, said first resistor disposed in a parallel relationship across said first leg of said inductor, said second circuit portion including a second capacitor and a second resistor, said second capacitor disposed in a parallel relationship across said second leg of said inductor, said second resistor disposed in a parallel relationship across said second leg of said inductor; providing an inductive admittance from said first leg of said inductor to a first communication transmitted within a first frequency band; and providing a capacitive admittance from said first circuit portion of said shunt network to a second communication transmitted within a second frequency band. Another embodiment of the invention is based on an apparatus, comprising: An apparatus, comprising: a circuit including an inductor and a shunt network, said inductor having a first leg and a second leg, said shunt network including a first circuit portion and a second circuit portion, said first circuit portion including a first capacitor and a first resistor, said first capacitor disposed in a parallel relationship across said first leg of said inductor, said first resistor disposed in a parallel relationship across said first leg of said inductor, and said second circuit portion including a second capacitor and a second resistor, said second capacitor disposed in a parallel relationship across said second leg of said inductor, said second resistor disposed in a parallel relationship across said second leg of said inductor, wherein said first leg of said inductor provides an inductive admittance to a first communication transmitted within a first frequency band, and said first circuit portion of said shunt network provides a capacitive admittance to a second communication transmitted within a second frequency band.

These, and other, embodiments of the invention will be better appreciated and understood when considered in conjunction with the following description and the accompanying drawings. It should be understood, however, that the following description, while indicating various embodiments of the invention and numerous specific details thereof, is given by way of illustration and not of limitation. Many substitutions, modifications, additions and/or rearrangements may be made within the scope of the invention without departing from the spirit thereof, and the invention includes all such substitutions, modifications, additions and/or rearrangements.

### BRIEF DESCRIPTION OF THE DRAWINGS

The drawings accompanying and forming part of this specification are included to depict certain aspects of the invention. A clearer conception of the invention, and of the components and operation of systems provided with the invention, will become more readily apparent by referring to the exemplary, and therefore nonlimiting, embodiments illustrated in the drawings, wherein like reference numerals (if they occur in more than one view) designate the same elements. The invention may be better understood by reference to one or more of these drawings in combination with the description presented herein. It should be noted that the features illustrated in the drawings are not necessarily drawn to scale.

FIG. 1 illustrates a block schematic view of the more important components of an ADSL repeater equipped subscriber loop, representing an embodiment of the invention.

FIG. 2 illustrates a block schematic view of the more important elements of a DMT signal processing flow (echo canceling mode), representing an embodiment of the invention.

FIG. 3 illustrates a block schematic view of a frequency-division duplexing mode for DMT-based ADSL (central office end shown), representing an embodiment of the invention.

FIG. 4 illustrates a block schematic view of an exemplary asymmetric digital subscriber loop repeater, representing an embodiment of the invention.

FIG. 5 illustrates a block schematic view of an outline of an extender circuit, representing an embodiment of the invention.

FIG. 6 illustrates a block schematic view of a circuit arrangement to replace load coils where a repeater is not deployed, representing an embodiment of the invention.

### DESCRIPTION OF PREFERRED EMBODIMENTS

The invention and the various features and advantageous details thereof are explained more fully with reference to the nonlimiting embodiments that are illustrated in the accompanying drawings and detailed in the following description. Descriptions of well known components and processing techniques are omitted so as not to unnecessarily obscure the invention in detail. It should be understood, however, that the detailed description and the specific examples, while indicating preferred embodiments of the invention, are given by way of illustration only and not by way of limitation. Various substitutions, modifications, additions and/or rearrangements within the spirit and/or scope of the underlying inventive concept will become apparent to those skilled in the art from this detailed description.

Within this application several publications are referenced by Arabic numerals within parentheses or brackets. Full citations for these, and other, publications may be found at the end of the specification immediately preceding the claims after the section heading References. The disclosures of all these publications in their entireties are hereby expressly incorporated by reference herein for the purpose of indicating the background of the invention and illustrating the state of the art.

The below-referenced U.S. Patent Applications disclose embodiments that were satisfactory for the purposes for which they are intended. The entire contents of U.S. patent application Ser. No. 09/476,770, filed Jan. 3, 2000 and U.S. patent application Ser. No. ______, filed Mar. 28, 2001 (attorney docket no. SYMM:029US) are hereby expressly incorporated by reference herein for all purposes.

The context of the invention includes digital subscriber loops. One species of digital subscriber loops is an asymmetrical digital subscriber loop. A preferred embodiment of the invention using ADSL repeaters (in place of load coils) enables a form of ADSL that uses the technique of frequency-division-duplexing to be provided to customers over very long loops.

The agreed upon standard for ADSL is the DMT (Discrete Multi-Tone) method. A premise underlying DMT is that the channel, namely the subscriber loop, does not have a “flat” frequency response. The attenuation at 1 Mhz (“high” frequency) can be as much as 60 dB greater than at 10 kHz (“low” frequency). Furthermore this attenuation varies with the length of the cable. By using Digital Signal Processing (“DSP”) techniques, specifically the theory of the Discrete Fourier Transform (“DFT”) and Fast Fourier Transform (“FFT”) for efficient implementation, the DMT method splits the available frequency band into smaller sub-channels of (approximately) 4 kHz. Each sub-channel is then loaded with a data rate that it can reliably support to give the desired aggregate data rate. Thus lower (center-)frequency sub-channels will normally carry a greater data rate than the sub-channels at higher (center-)frequencies.

The underlying principle of the DSL repeater is the need to combat the loss in the actual cable (subscriber loop). This is achieved by introducing gain. Since amplifiers are for the most part unidirectional devices, one approach is to perform a 2w-to-4w conversion and put amplifiers in each direction. This is most easily achieved when the directions of transmission are in disjoint spectral bands. The direction of transmission are in disjoint spectral bands if the directions of transmission are separated in frequency (i.e. frequency-division duplexing), then simple filter arrangements can provide the separation.

Most loop plant provide for access to the cable, which may be buried underground, approximately every 6000 feet. This was the practice to allow for the provision of load coils. Thus the natural separation between repeaters is (approximately) 6000 feet. The repeater may be placed in parallel with a load coil if the DSL needs to coexist with POTS.

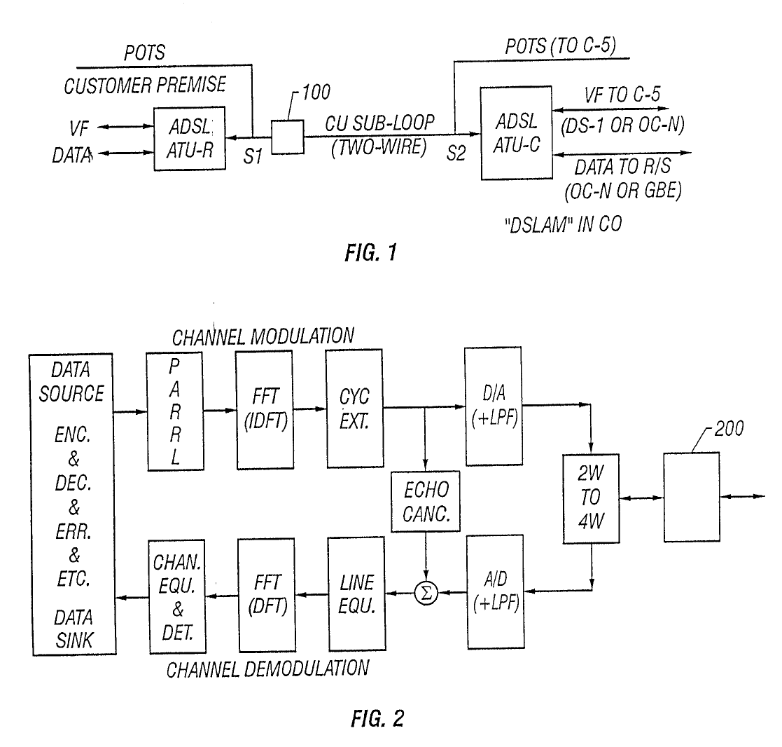

Referring to FIG. 1, a general architecture for providing an asymmetric digital subscriber loop (ADSL) is depicted. A subscriber loop is the actual two-wire copper pair that originates at the Central Office and terminates at the subscriber's premise. For providing ADSL over long loops, an ADSL repeater, 100, may be included. At the customer premise the handset (POTS) is “bridged” onto the subscriber loop at point labeled S 1. In some forms of ADSL this bridging can be achieved using passive filters (called a “splitter”) to demarcate the frequency bands where voice and data reside. Similarly, a splitter may be employed at the central office (CO) at point S2. Central office equipment that interfaces to ADSL provisioned lines is often embodied as a multiplexer called a “DSLAM” (Digital Subscriber Line Access Multiplexer). The data component is aggregated into an optical or high-bit-rate signal for transport to the appropriate terminal equipment. The capacity of ADSL allows for additional voice circuits (shown as VF in FIG. 1) to be carried in digital format as part of the ADSL data stream. This content is usually (though not always) destined to a Class-5 switch.

The term approximately, as used herein, is defined as at least close to a given value (e.g., preferably within 10% of, more preferably within 1% of, and most preferably within 0.1% of). The term coupled, as used herein, is defined as connected, although not necessarily directly, and not necessarily mechanically. The term substantially, as used herein, is defined as at least approaching a given state (e.g., preferably within 10% of, more preferably within 1% of, and most preferably within 0.1% of).

Given that a large installed loop plant exists, the invention can include retrofit installation. Part of the retrofit installation procedure involves removal of all load coils, and bridge-taps that may be present on the (existing) subscriber loop. Based on telephone company records, the (approximate) distance between the subscriber premise and the serving Central Office can be estimated to decide whether DSL can be provided in the first place. If DSL can indeed be provided, an estimate of the class (and thus the data carrying capacity) is made. If not, then the telephone company may choose to provide a lower bit-rate service such as BRI or, in some cases, not be able to provide any service beyond POTS.

Signals from both directions can coexist on the cable pair and such transmission is referred to as “2-wire”. This form is perfectly adequate for analog signals (speech). In digital transmission systems the two directions are separated (logically, if not physically) and such transmission is termed “4-wire”. Two common approaches to achieving this action are “echo canceling” and frequency-division-duplexing (“FDD”). Both approaches can be supported by the DMT method.

Referring to FIG. 2, a signal processing flow in a DMT-based ADSL transmission unit (“ATU”) that employs echo cancellation is depicted. The transmit (“modulation” direction) side is considered first. The data to be transmitted is first processed to include error correction by a ENC. & DEC. & ERR. & ETC. unit. It is then formatted into multiple “parallel” channels via a PARRL processing unit. It is then placed in the appropriate frequency slot via a FFT processing unit. The notion of “cyclic extension” is unique to DMT and involves increasing the sampling rate by insertion of additional samples via a CYC. EXT. processing unit. This composite signal is converted to analog via a D/A converter and coupled to the line via a 2w-to-4w converter. An ADSL repeater 200 is coupled to the 2w-to-4w converter.

Ideally the entire signal from the D/A converter is transmitted to the distant end via the 2w-to-4w converter. However, in practice some amount “leaks” from the 2w-to-4w converter toward a A/D converter. This leakage can be termed the “echo.” The receive side (“demodulation” direction) is now considered. The signal from the distant end arrives at the 2w-to-4w converter via the repeater 200 and is directed to the A/D converter for conversion to digital format. Subsequent processing includes line equalization via the LINE EQU. unit, fast Fourier transformation via the FFT unit and then channel equalization and data detection via the CHAN. EQU. & DET. unit. Processing is then handed to the unit that does the error detection and/or correction and reorganizing into the appropriate format. To remove the echo (the component of the transmit signal that leaks across the 2w-to-4w converter) an echo cancellation filter is employed. This is a digital filter that mimics the echo path and thus the output of the filter labeled “Echo Canc” is a “replica” of the echo and by subtraction of this signal from the received signal at a summation unit, the net echo can be substantially reduced. Thus 4w operation is achieved even though the medium is merely 2w. The spectral content of signals in the two directions can have significant overlap but are sufficiently separated by the echo cancellation technique.

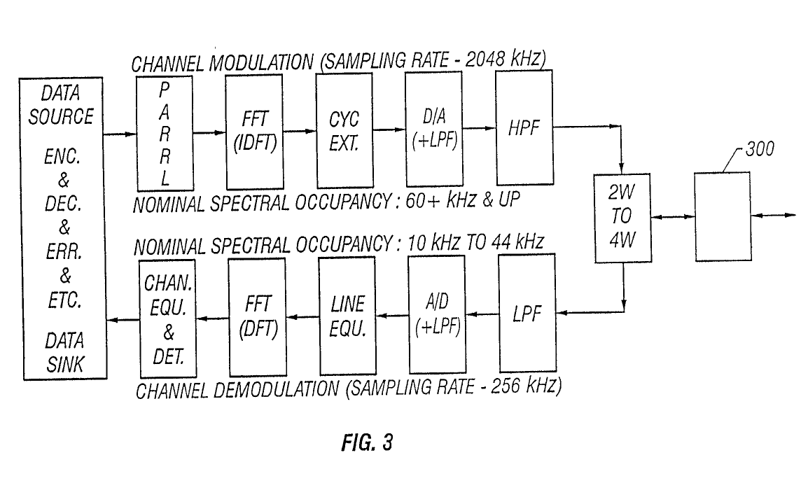

Referring to FIG. 3, a frequency-division duplexing (FDD) mode of DMT for ADSL is depicted. The “back-end” of the FDD version of DMT-based ADSL is substantially the same as the echo-canceling version illustrated in FIG. 2.

Referring again to FIG. 3, the frequency range used for Upstream versus Downstream is vendor specific. Standards-compliant ADSL uses a total bandwidth of roughly 20 kHz to 1.1 MHz. In a preferred embodiment, the upstream occupies between 20 kHz and X₁ kHz whereas the downstream signal occupies the band between X₂ kHz and 1.1 MHz. X₂ should be substantially greater than X₁ to allow for frequency roll-off of the filters used to demarcate the upstream and down-stream bands. One suitable choice is X₁=110 kHz and X₂=160 kHz. The specific choice of these band edges can be made a design parameter and different “models” of the repeater can be fabricated with different choices of band edges.

Still referring to FIG. 3, a high pass filter HPF unit is coupled to the D/A units. A 2w-to-4w converter is coupled to the HPF unit. The 2w-to-4w converter is also coupled to a low pass filter LPF unit which is in-turn coupled to the A/D unit. An ADSL repeater 300 is coupled to the 2W-to-4w converter.

The underlying principle of the ADSL extender is the need to combat the loss in the actual cable (subscriber loop). This is achieved by introducing gain. Since amplifiers are for the most part unidirectional devices, we need to, in essence, perform a 2w-to-4w conversion and put amplifiers in each direction. This is most easily achieved when the directions of transmission are in disjoint spectral bands. That is, if the directions of transmission are separated in frequency (i.e. frequency-division duplexing), then simple filter arrangements can provide the separation.

Most loop plant provide for access to the cable, which may be buried underground, approximately every 6000 feet. This was the practice to allow for the provision of load coils. Thus, the natural separation between repeaters is (approximately) 6000 feet. The repeater may be placed in parallel with a load coil if the ADSL needs to coexist with POTS.

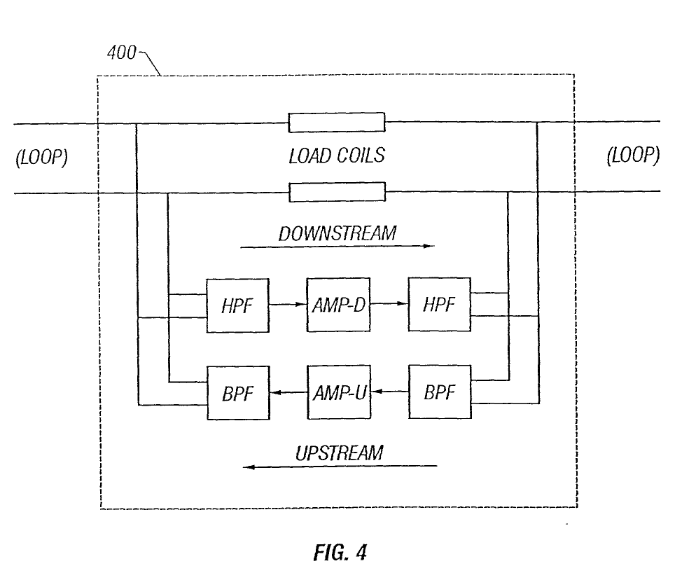

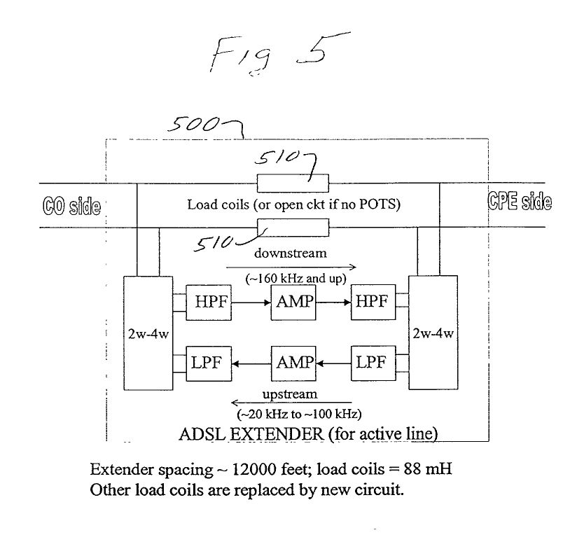

The particular description of an ADSL repeater provided in FIG. 4 is suitable for the DMT-based ADSL transmission scheme employing frequency-division duplexing (FDD). The form discussed assumes that POTS and ADSL will coexist (simultaneously). Of course, the invention is not limited to this ADSL FDD example.

Referring to FIG. 4, an outline of the functional blocks in an ADSL repeater 400 are depicted. For convenience certain functions such as power and control are not shown in FIG. 4. Power and control units can be coupled to the ADSL repeater 400. Although not required, two load coils are shown as part of the repeater 400. When load coils are deployed in a loop, the loop is split and the load coils are spliced in as indicated by the series connections of the inductors (load coils) with the loop. This can be termed in line with loop.

The load coils provide a very high impedance at high frequencies and thus for the range of frequencies where ADSL operates the load coils look essentially like open circuits. The 2w-to-4w arrangement is not explicitly shown in FIG. 4 but is implied. Since the two directions are separated in frequency, the 2w-to-4w arrangement can be quite simple. A bandpass filter BPF isolates the frequency band from 20 kHz to 110 kHz (approximately) and thus the upstream signal is amplified by an amplifier AMP-U. In this particular example, the gain introduced can compensate for the attenuation introduced by approximately 6000 feet of cable at 27 kHz (or approximately the middle of the band). The highpass filters HPF separates out the band above 160 kHz (approximately) and thus the downstream signal is amplified by an amplifier AMP-D. Again, in this particular example, the gain introduced compensates for the attenuation of approximately 6000 feet of cable at 600 kHz (again, roughly the middle of the band).

Since the frequency response of the cable is not “flat” the amplifiers can be designed such that, in conjunction with the filters, they provide a rough amplitude equalization of the cable response over the appropriate frequency band, for example, approximately 20 kHz to 110 kHz upstream and approximately 160 kHz to 1 MHz downstream. The choice of frequency bands is, preferably, 20 kHz to 110 kHz for the upstream direction and 160 kHz to 1.1 MHz for the downstream direction.

If POTS need not be supported, then the load coils are superfluous and can be left “open”. Further, if the need for load coils is obviated, the separation of the units becomes a design parameter, independent of load coil placement. A suitable separation of Extenders in this situation is between 7 and 12 kft, and the unit can then be referred to as a “Mid-Span Extender”. Clearly, the gains required for the mid-span extender are commensurate with the expected separation.

An ADSL Repeater is well suited for providing ADSL services over long loops which may have been precluded based on loop length and presence of load coils. As described it is a simple mechanism for amplifying the upstream and downstream signals, compensating for the loss in the subscriber loop cable. Separating repeaters by approximately 6000 feet is appropriate since this the nominal distance between points on the cable where load coils were introduced in the past. Cross-over networks based on highpass and bandpass filters can define the upstream and downstream bandwidths used by the DMT-based ADSL units at the CO and CPE operating in a frequency-division duplex mode.

Installing equipment in the cable plant introduces two important considerations. One is the need to provide power. The second is to provide the means to verify operation and isolate problems.

Subscriber loop cable usually comes in bundles of 25 pairs. That is each bundle can provide service to 25 telephone lines. One embodiment of the invention can use the 25 pairs to provide just 20 ADSL connections. This leaves 4 pairs to carry power for the repeaters, and 1 pair to carry control information.

Each 25-pair “repeater housing” can include one controller (microprocessor) and modems that convert the digital control information to (and from) analog for transport over the control pair. These controllers can operate in a “daisy chain” which allows the central office end to query for status, or control the operation of, any repeater housing in the path. For long loops, those exceeding 18 thousand feet, there may be as many as 4 or 5 (or more) repeater housings connected in series (approximately 6000 feet apart). The control information will include commands for maintenance and provisioning information.

The provisioning information relates to the mode of operation of each of the 20 pair of cable that carry ADSL. One mode is “normal”, where the repeater is operating and the load coils are in the circuit. Another mode is “no-ADSL-repeater” wherein the repeaters are not part of the circuit. This latter mode has two “sub-modes”. The load-coils may be in the circuit or be removed. The last sub-mode is appropriate if the loop is actually short and we do not need the repeaters and the load coils need to be removed. Of course, other modes of operation can be conceived of.

For test and maintenance purposes, the central office end needs to be capable of forcing any one chosen repeater (on the subscriber loop under test) to enter a loop-back state. That is, a test signal sent from the central office is “looped back” at the chosen repeater and the condition of the loop up to that chosen repeater can be validated. Other test and maintenance features must be provided to support the operating procedures of the phone company.

For providing loop-back through the repeater, the following approach can be used. It can be appreciated that the upstream and downstream signal bands are disparate and non-overlapping. Thus, the notion of loop-back is not simple. One approach can use a two-tone test signal that is within the downstream spectral band. For example, the tone frequencies could be 200 kHz and 250 kHz. When commanded to go into loop-back, the designated repeater introduces a nonlinear element into the circuit. The nonlinear element will create different combinations of the sums and difference frequencies. In particular, the nonlinear element can generate the difference frequency, 50 kHz in the example cited. This signal is within the frequency band of the upstream direction and thus can be looped back. The central office end can monitor the upstream path for this (difference) frequency and thus validate the connectivity up to the repeater in loop-back state.

The form of extender where load coils are not being replaced is the mid-span extender. Placement of a mid-span extender is not constrained by the placement of load coils but, as a matter of practice, the phone company usually has a manhole or equivalent construction where load coils are (normally) situated and these locations would be logical places for deployment of a mid-span extender as well. When a mid-span extender is employed, the load coil removal would follow normal telephone company practice.

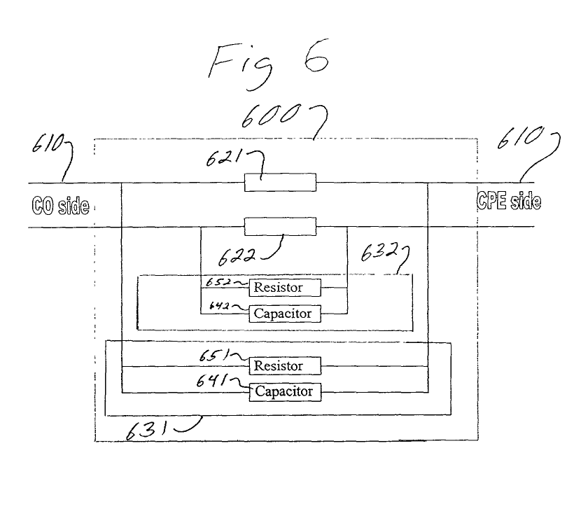

The basic circuit outline 500 of the extender unit is shown in FIG. 5. The extender unit includes a first 2w-4w and a second 2w-4w. For the case of a “load coil replacement”, the 88 mH inductors 510 would be present and the gains adjusted for compensating for (roughly) 6000 feet of cable. The same circuit arrangement would apply to the mid-span extender case wherein the 88 mH coils would not be present and the gains adjusted for X feet of cable (X could be in the neighborhood of 10,000 feet).

The invention can include a modified load coil circuit that provides a shunt network that permits high frequency signals to avoid the impedance presented by the load coil. If the resulting circuit does not need to support POTS, the modified load coil circuit can omit the coil(s). The invention can include replacing some or all of the load coils in a DSL with corresponding modified load coil circuits with shunt networks. If only some of the load coils in a DSL are replaced with modified load coil circuits, the remaining coils need to be addressed. The invention can be combined with extenders that provide a gain. For example, if an extender is placed between load coils located at 9 kft and 15 kft, the load coils present at 9 kft and 15 kft must be addressed. For instance, the coil closer to the extender can be short-circuited and the other coil can be replaced by a modified load coil circuit arrangement that includes the shunt network.

Ideally, a repeater will be placed at each load-coil-location. However, since the repeater amplifiers require a power source it is advisable to have as few as possible so that the telephone company is relieved of the requirement of providing power at so many locations. At load-coil locations where no power is provided, the load coil can be replaced by the circuit arrangement depicted in FIG. 6. Of course, this approach can also be used where power is available, albeit without a signal gain.

Referring to FIG. 6, a modified load coil circuit 600 is coupled to a transmission medium 610 between a central office (CO) side and a customer premises equipment (CPE) side. The circuit 600 includes an inductor composed of a first inductor coil 621 and a second inductor coil 622. The first inductor coil 621 can be termed a first leg and the second inductor coil 622 can be termed a second leg. Each of the inductor coils 621, 622 can have a value of approximately 44 mH yielding a total inductor value of 88 mH. The circuit 600 includes a shunt network composed of a first circuit portion 631 and a second circuit portion 632. The first circuit portion 631 can include a first capacitor 641 and a first resistor 651. The first capacitor 641 is disposed in a parallel relationship across the first leg of the inductor. The first resistor is also disposed in a parallel relationship across the first leg of the inductor. Similarly, the second circuit portion 632 can include a second capacitor 642 and a second resistor 652. The second capacitor 642 is disposed in a parallel relationship across the second leg of said inductor. Similarly, the second resistor 652 is disposed in a parallel relationship across said second leg of said inductor.

The first leg of the inductor provides an inductive admittance to a first communication transmitted within a first frequency band. The first communication can be POTS. The first circuit portion 631 of the shunt network provides a capacitive admittance to a second communication transmitted within a second frequency band. The second communication can be ADSL. The second leg of the inductor provides an inductive admittance for the return path of said first communication transmitted within said first frequency band. The second circuit portion 632 of the shunt network provides a capacitive admittance for the return path of said second communication transmitted within said second frequency band.

The second leg of the inductor and the second circuit portion 632 of the shunt network may be said to compose part of a return path. Most telecom transmission media are balanced. The subscriber loop should be balanced. The notion of balanced is that there will be an equivalent set of components in both the forward and return paths. If the first leg of the inductor is termed “forward,” then the second leg of the inductor should be termed “return.”

The modified load coil circuit 600 can be utilized in the context of a DSL where gain providing extenders replace legacy load coils every approximately 12000 feet with other load coils replaced by the modified load coil circuit 600. Preferred embodiments of the invention can be identified one at a time by selecting a value for R or C and then collecting frequency response data while the other variable (C or R) is swept across a range.

The circuit arrangement can be utilized in conjunction with the traditional load coil, typically 88 mH, which is installed as 44 mH in each leg of the 2-wire loop. Each leg is one-half the total inductance value. The invention can include providing each leg with a shunt network comprising a capacitor and a resistor. The values of these components can be denoted by C and R, respectively. The value required for the capacitor is determined by making the resonant, or cross-over, frequency 10 kHz (approximately). Thus at frequencies below 10 kHz (approximately) the arrangement appears inductive, providing the load coil functionality for the voice-band (up to about 4 kHz). At frequencies above 10 kHz (approximately) the arrangement appears capacitive, providing the pass-through functionality for the ADSL band (above about 20 kHz). The provision of the resistor, which is a small value, is to ensure that the arrangement is “damped” and does not have the behavior of appearing as an open circuit at the resonant frequency. Suitable values for C and R are 0.0068 μF (6.8 nanofarads) and 5 ohms, respectively. Of course, the invention is not limited to particular C and/or R values.

The invention can include retrofitting an existing coil pair with the shunt network.

Alternatively, the invention can include swapping out an existing coil pair for a replacement coil pair that is coupled to the shunt network.

To demonstrate the efficacy of this arrangement, we provide computed frequency response for various lengths of cable in the following tables. The transmission line parameters of the cable were obtained from Bellcore (now Telcordia) document Technical Reference TR-NPL-000157, titled “Secondary Channel in the Digital Data System: Channel Interface Requirements”, where the transmission line parameters of resistance, capacitance, inductance, and conductance, all per unit length, of different gauges and types of subscriber cable are provided. Specifically, the parameters used in the calculations were for 24 and 26 gauge PIC cable at 70 degrees Fahrenheit. For computing the voice-band frequency response the source and termination impedances were assumed to be 900 ohms and for the ADSL band the source and termination impedances were assumed to be 100 ohms. The response values are computed in terms of gain (negative values indicate a loss) in dB.

The following table, Table 1, provides the calculations for 6000 feet of 24 gauge PIC cable using the parameters provided for 70 degrees F.

TABLE 1
6000 feet of 24 gauge PIC cable at 70 degrees (F.).

| Frequency | Response w/o | Response with load- | Response with new |
|---|---|---|---|
| (kHz) | loading | coils (H-88) | loading circuit |
| 0.1 | −1.40 | −1.40 | −1.44 |
| 0.5 | −1.48 | −1.41 | −1.45 |
| 1.0 | −1.73 | −1.44 | −1.49 |
| 3.0 | −3.70 | −2.77 | −3.41 |
| 3.4 | −4.18 | −3.78 | −4.93 |
| 4.0 | −4.89 | −5.92 | −8.02 |
| 20.0 | −9.53 | −37.83 | −27.08 |
| 80.0 | −13.12 | −59.33 | −23.13 |
| 100.0 | −13.81 | −61.72 | −21.81 |
| 150.0 | −15.47 | −66.97 | −21.07 |
| 200.0 | −17.15 | −71.49 | −21.16 |
| 300.0 | −20.40 | −78.42 | −22.79 |
| 500.0 | −26.17 | −88.82 | −27.31 |
| 800.0 | −33.00 | −99.92 | −33.54 |
| 1000.0 | −37.08 | −106.03 | −37.45 |

The following table, Table 2, provides the calculations for 6000 feet of 26 gauge PIC cable using the parameters provided for 70 degrees F.

TABLE 4.2
6000 feet of 26 gauge PIC cable at 70 degrees (F.).

| Frequency | Response w/o | Response with load- | Response with new |
|---|---|---|---|
| (kHz) | loading | coils (H-88) | loading circuit |
| 0.1 | −2.14 | −2.14 | −2.17 |
| 0.5 | −2.22 | −2.15 | −2.19 |
| 1.0 | −2.48 | −2.19 | −2.23 |
| 3.0 | −4.57 | −3.35 | −3.91 |
| 3.4 | −5.07 | −4.26 | −5.31 |
| 4.0 | −5.82 | −−6.28 | −8.31 |
| 20.0 | −13.37 | −39.97 | −29.56 |
| 80.0 | −19.09 | −64.37 | −28.57 |
| 100.0 | −19.98 | −67.23 | −27.78 |
| 150.0 | −21.77 | −73.02 | −27.40 |
| 200.0 | −23.42 | −77.46 | −27.49 |
| 300.0 | −26.76 | −84.56 | −29.21 |
| 500.0 | −33.22 | −95.68 | −34.4 |
| 800.0 | −41.68 | −108.44 | −42.25 |
| 1000.0 | −46.80 | −115.61 | −47.19 |

The following table, Table 3, provides the calculations for 12000 feet of 24 gauge PIC cable using the parameters provided for 70 degrees F.

TABLE 3
12000 feet of 24 gauge PIC cable at 70 degrees (F.).

| Frequency | Response w/o | Response with load- | Response with new |
|---|---|---|---|
| (kHz) | loading | coils (H-88) | loading circuit |
| 0.1 | −2.62 | −2.62 | −2.68 |
| 0.5 | −2.98 | −2.64 | −2.70 |
| 1.0 | −3.92 | −2.68 | −2.75 |
| 3.0 | −8.82 | −4.39 | −5.99 |
| 3.4 | −9.67 | −7.90 | −11.36 |
| 4.0 | −10.83 | −12.01 | −20.29 |
| 20.0 | −19.20 | −78.41 | −56.76 |
| 80.0 | −26.39 | −118.37 | −45.85 |
| 100.0 | −27.71 | −123.07 | −43.68 |
| 150.0 | −31.00 | −133.86 | −42.11 |
| 200.0 | −34.35 | −142.76 | −42.38 |
| 300.0 | −40.83 | −156.72 | −45.61 |
| 500.0 | −52.36 | −177.54 | −54.63 |
| 800.0 | −66.02 | −192.98 | −67.10 |
| 1000.0 | −74.17 | −193.91 | −74.91 |

The following table, Table 4, provides the calculations for 12000 feet of 26 gauge PIC cable using the parameters provided for 70 degrees F.

TABLE 4
12000 feet of 26 gauge PIC cable at 70 degrees (F.).

| Frequency | Response w/o | Response with load- | Response with new |
|---|---|---|---|
| (kHz) | loading | coils (H-88) | loading circuit |
| 0.1 | −3.86 | −3.85 | −3.91 |
| 0.5 | −4.26 | −3.91 | −3.97 |
| 1.0 | −5.33 | −4.03 | −4.09 |
| 3.0 | −10.66 | −5.87 | −7.21 |
| 3.4 | −11.58 | −8.93 | −12.03 |
| 4.0 | −12.85 | −15.53 | −20.65 |
| 20.0 | −26.50 | −81.58 | −60.57 |
| 80.0 | −38.38 | −128.53 | −57.00 |
| 100.0 | −40.12 | −134.55 | −55.81 |
| 150.0 | −43.65 | −146.12 | −54.85 |
| 200.0 | −46.92 | −154.93 | −55.09 |
| 300.0 | −53.57 | −169.10 | −58.49 |
| 500.0 | −66.48 | −189.48 | −68.83 |
| 800.0 | −83.39 | −193.96 | −84.51 |
| 1000.0 | −93.62 | −193.97 | −94.40 |

The following table, Table 5, provides the calculations for 18000 feet of 24 gauge PIC cable using the parameters provided for 70 degrees F.

TABLE 5
18000 feet of 24 gauge PIC cable at 70 degrees (F.).

| Frequency | Response w/o | Response with load- | Response with new |
|---|---|---|---|
| (kHz) | loading | coils (H-88) | loading circuit |
| 0.1 | −3.70 | −3.68 | −3.77 |
| 0.5 | −4.54 | −3.77 | −3.86 |
| 1.0 | −6.46 | −3.92 | −4.02 |
| 3.0 | −13.52 | −4.94 | −6.64 |
| 3.4 | −14.58 | −10.68 | −17.34 |
| 4.0 | −16.03 | −24.34 | −32.84 |
| 20.0 | −28.81 | −119.00 | −86.46 |
| 80.0 | −39.65 | * | −68.58 |
| 100.0 | −41.61 | * | −65.55 |
| 150.0 | −46.53 | * | −63.16 |
| 200.0 | −51.54 | * | −63.59 |
| 300.0 | −61.25 | * | −68.42 |
| 500.0 | −78.55 | * | −81.96 |
| 800.0 | −99.04 | * | −100.65 |
| 1000.0 | −111.26 | * | −112.37 |

The following table, Table 6, provides the calculations for 18000 feet of 26 gauge PIC cable using the parameters provided for 70 degrees F.

TABLE 6
18000 feet of 26 gauge PIC cable at 70 degrees (F.).

| Frequency | Response w/o | Response with load- | Response with new |
|---|---|---|---|
| (kHz) | loading | coils (H-88) | loading circuit |
| 0.1 | −5.32 | −5.29 | −5.36 |
| 0.5 | −6.32 | −5.51 | −5.59 |
| 1.0 | −8.53 | −5.94 | −6.03 |
| 3.0 | −16.44 | −7.50 | −9.01 |
| 3.4 | −17.68 | −12.47 | −18.30 |
| 4.0 | −19.38 | −24.99 | −33.26 |
| 20.0 | −39.57 | −123.20 | −91.58 |
| 80.0 | −57.67 | −190.28 | −85.43 |
| 100.0 | −60.26 | * | −83.85 |
| 150.0 | −65.52 | * | −82.30 |
| 200.0 | −70.39 | * | −82.70 |
| 300.0 | −80.19 | * | −87.76 |
| 500.0 | −99.74 | * | −103.26 |
| 800.0 | −125.09 | * | −126.78 |
| 1000.0 | −140.43 | * | −141.61 |

Similar tables can be generated for other lengths of cable. The use of an asterisk implies that the loss is greater than 200 dB. The following observations are generally true for all lengths and wire gauges. We can define the “efficacy” of the new arrangement relative to the conventional load-coil method with regard to the performance in the voice-band and in the ADSL band. For the voice-band we use the notion of “skew” defined as the difference in response between 1 kHz and 3.4 kHz, which correspond to the reference frequency used for testing voice-grade circuits (test-tone is defined as a frequency of 1 kHz) and the edge of the band associated with speech circuits (3.4 kHz). Even at 18 kft of 26 gauge cable, the skew with the new arrangement is only about 6 dB worse than conventional loading. There is no comparison in the ADSL band. The new arrangement is clearly superior in the ADSL band. Also observable is a very nice property of the new arrangement. Whereas, generally speaking, the pass-through behavior in the ADSL band is evident, the new arrangement does in fact provide a significant benefit. Note that the high frequency response, that is, the response in the ADSL band, is much more uniform with the new arrangement than it is for ordinary unloaded cable. This “equalization” implies that the behavior of the cable with mid-span extenders deployed will be superior when load-coils are replaced with the new arrangement than when the load-coils are removed altogether.

The quality of the (simultaneous) POTS circuit can be made essentially the same as that of a conventional loaded loop by replacing the load-coil with a modified circuit comprising a shunt capacitor across each leg of the load coil, each leg being in-line with one leg of the two-wire loop. To summarize, the mid-span extenders can be used to provide ADSL over long subscriber loops; and POTS and ADSL can be supported simultaneously by providing a load-coil as part of the mid-span extender circuit.

The invention can also utilize data processing methods that transform signals from the digital subscriber loop to actuate interconnected discrete hardware elements. For example, to remotely adjust the resistors and capacitor (assuming they are variable components) and/or reconfigure extender(s) and/or repeater(s) after initial installation using network control signals sent over the DSL.

The invention can also be included in a kit. The kit can include some, or all, of the components that compose the invention. The kit can be an in-the-field retrofit kit to improve existing systems that are capable of incorporating the invention. The kit can include software, firmware and/or hardware for carrying out the invention. The kit can also contain instructions for practicing the invention. Unless otherwise specified, the components, software, firmware, hardware and/or instructions of the kit can be the same as those used in the invention.

The term deploying, as used herein, is defined as designing, building, shipping, installing and/or operating. The term means, as used herein, is defined as hardware, firmware and/or software for achieving a result. The term program or phrase computer program, as used herein, is defined as a sequence of instructions designed for execution on a computer system. A program, or computer program, may include a subroutine, a function, a procedure, an object method, an object implementation, an executable application, an applet, a servlet, a source code, an object code, a shared library/dynamic load library and/or other sequence of instructions designed for execution on a computer system. The terms including and/or having, as used herein, are defined as comprising (i.e., open language). The terms a or an, as used herein, are defined as one or more than one. The term another, as used herein, is defined as at least a second or more.

### Practical Applications of the Invention

A practical application of the invention that has value within the technological arts is local digital subscriber loop service. Further, the invention is useful in conjunction with digital subscriber loop networks (such as are used for the purpose of local area networks or metropolitan area networks or wide area networks), or the like. There are virtually innumerable uses for the invention, all of which need not be detailed here.

### Advantages of the Invention

A digital subscriber loop repeater, representing an embodiment of the invention can be cost effective and advantageous for at least the following reasons. The invention permits DSL to be provided on long loops. The invention permits DSL to be provided on loaded loops. The new scheme is especially appropriate for providing ADSL over long subscriber loops which require “repeaters” or “extenders”. While conventional DSL installation requires that all load coils be removed from a loop, the invention can include the replacement of these load coils with what can be termed to be “a modified load coil circuit.” In addition, the invention improves quality and/or reduces costs compared to previous approaches.

All the disclosed embodiments of the invention disclosed herein can be made and used without undue experimentation in light of the disclosure. Although the best mode of carrying out the invention contemplated by the inventors is disclosed, practice of the invention is not limited thereto. Accordingly, it will be appreciated by those skilled in the art that the invention may be practiced otherwise than as specifically described herein.

Further, the individual components need not be formed in the disclosed shapes, or combined in the disclosed configurations, but could be provided in virtually any shapes, and/or combined in virtually any configuration. Further, the individual components need not be fabricated from the disclosed materials, but could be fabricated from virtually any suitable materials.

Further, variation may be made in the steps or in the sequence of steps composing methods described herein. Further, although the digital subscriber loop repeaters described herein can be separate modules, it will be manifest that the repeaters may be integrated into the system with which they are associated. Furthermore, all the disclosed elements and features of each disclosed embodiment can be combined with, or substituted for, the disclosed elements and features of every other disclosed embodiment except where such elements or features are mutually exclusive.

It will be manifest that various substitutions, modifications, additions and/or rearrangements of the features of the invention may be made without deviating from the spirit and/or scope of the underlying inventive concept. It is deemed that the spirit and/or scope of the underlying inventive concept as defined by the appended claims and their equivalents cover all such substitutions, modifications, additions and/or rearrangements.

The appended claims are not to be interpreted as including means-plus-function limitations, unless such a limitation is explicitly recited in a given claim using the phrase(s) “means for” and/or “step for.” Subgeneric embodiments of the invention are delineated by the appended independent claims and their equivalents. Specific embodiments of the invention are differentiated by the appended dependent claims and their equivalents.

### REFERENCES

1. Walter Y. Chen, DSL. Simulation Techniques and Standards Development for Digital Subscriber Line Systems, Macmillan Technical Publishing, Indianapolis, 1998. ISBN: 1-57870-017-5.

2. Padmanand Warrier and Balaji Kumar, XDSL Architecture, McGraw-Hill, 1999. ISBN: 0-07-135006-3.

3. “G.992.1, Asymmetrical Digital Subscriber Line (ADSL) Transceivers,” Draft ITU Recommendation, COM 15-131.

4. “G.992.2, Splitterless Asymmetrical Digital Subscriber Line (ADSL) Transceivers,” Draft ITU Recommendation COM 15-136.

5. Kishan Shenoi, Digital Signal Processing in Telecommunications, Prentice-Hall, Inc., Englewood Cliffs, N.J., 1995. ISBN: 0-13-096751-3.

6. The Electrical Engineering Handbook, CRC Press, (Richard C. Dorf et al. eds.), 1993.

What is claimed is:

1. A method, comprising:
providing a circuit to extend a transmission medium, said circuit including an inductor and a shunt network, said inductor including a first leg and a second leg, said shunt network including a first circuit portion and a second circuit portion, said first circuit portion including a first capacitor and a first resistor, said first capacitor disposed in a parallel relationship across said first leg of said inductor, said first resistor disposed in a parallel relationship across said first leg of said inductor, said second circuit portion including a second capacitor and a second resistor, said second capacitor disposed in a parallel relationship across said second leg of said inductor, said second resistor disposed in a parallel relationship across said second leg of said inductor;
providing an inductive admittance from said first leg of said inductor to a first communication transmitted within a first frequency band;
providing a capacitive admittance from said first circuit portion of said shunt network to a second communication transmitted within a second frequency band;
providing another inductive admittance from said second leg of said inductor for the return path for said first communication transmitted within said first frequency band; and
providing another capacitive admittance from said second circuit portion of said shunt network for the return path for said second communication transmitted within said second frequency band.

2. The method of claim 1, wherein said first frequency band is lower than both a resonant cross-over frequency of said circuit and said second frequency band

3. The method of claim 1, wherein providing said circuit includes replacing a load coil pair at a load coil location of said transmission medium with said circuit.

4. The method of claim 1, wherein providing said circuit includes modifying a load coil pair at a load coil location of said transmission medium.

5. The method of claim 1, wherein providing said circuit includes:
selecting a location on said transmission medium;
cutting said transmission medium at said location; and
splicing said circuit into said transmission medium at said location.

6. The method of claim 1, further comprising simultaneously supporting POTS and ADSL with said circuit.

7. An apparatus, comprising:
a circuit including an inductor and a shunt network, said inductor having a first leg and a second leg, said shunt network including a first circuit portion and a second circuit portion, said first circuit portion including a first capacitor and a first resistor, said first capacitor disposed in a parallel relationship across said first leg of said inductor, said first resistor disposed in a parallel relationship across said first leg of said inductor, and said second circuit portion including a second capacitor and a second resistor, said second capacitor disposed in a parallel relationship across said second leg of said inductor, said second resistor disposed in a parallel relationship across said second leg of said inductor,
wherein said first leg of said inductor provides an inductive admittance to a first communication transmitted within a first frequency band, said first circuit portion of said shunt network provides a capacitive admittance to a second communication transmitted within a second frequency band, said second leg of said inductor provides another inductive admittance for the return path for said first communication transmitted within said first frequency band, and said second circuit portion of said shunt network provides another capacitive admittance for the return path for said second communication transmitted within said second frequency band.

8. The apparatus of claim 7, wherein said first frequency band is lower than both a resonant cross-over frequency and said second frequency band.

9. The apparatus of claim 7, further comprising said transmission medium.

10. The apparatus of claim 9, wherein said transmission medium includes an asymmetric digital subscriber loop.

11. The apparatus of claim 10, wherein said circuit is interposed at an intermediate point of said asymmetric digital subscriber loop to extend said asymmetric digital subscriber loop from a provider end and a subscriber end.

12. The apparatus of claim 9, further comprising a gain providing extender located between a central office and a customer premises.

13. The apparatus of claim 9, further comprising a gain providing mid-span extender located between the circuit and said customer premises.

14. The apparatus of claim 7, wherein POTS and ADSL can be supported simultaneously.

15. The apparatus of claim 14, wherein a capacitance of both said first capacitor and said second capacitor are selected to define a resonant cross-over frequency of approximately 10 kHz.

16. The apparatus of claim 7, wherein the inductor has an inductance of approximately 88 mH.

17. The apparatus of claim 7, wherein both the first leg and the second leg are not short circuited.

18. The apparatus of claim 7, wherein both the first leg and the second leg are short circuited.

19. The apparatus of claim 7, wherein both the first capacitor and the second capacitor have a capacitance of from approximately 0.005 to approximately 0.008 μF.

20. The apparatus of claim 19, wherein the capacitance is approximately 0.0069 μF.

21. The apparatus of claim 7, wherein both said first resistor and said second resistor have a resistance of from approximately 2 to approximately 7 ohms.

22. The apparatus of claim 21, wherein said resistance is approximately 5 ohms.

23. A method for supporting digital data on a previously deployed transmission medium that supports plain old telephone service voice communications, comprising:
selecting an intermediate point on said previously deployed transmission medium between a first load coil location and a second load coil location to extend said previously deployed transmission medium, said previously deployed transmission medium connecting said first load coil location to said second load coil location;
providing an extender circuit at said intermediate point, said extender circuit having a first end and a second end, said first end coupled to said first load coil location and said second end coupled to said second load coil location; and
retrofitting said first load coil location and said second load coil location.

24. The method of 25, wherein retrofitting includes:
short-circuiting said first load coil location.

25. The method of claim 24, wherein retrofitting includes providing a modified load coil circuit at said second load coil location to modify said second load coil location, said modified load coil circuit including a first circuit portion and a second circuit portion, said first circuit portion including a first shunt capacitor and a first shunt resistor across said second load coil location, and said second circuit portion including a second shunt capacitor and a second shunt resistor across said second load coil location.

26. The method of 25, wherein retrofitting includes removing a first load coil from said first load coil location.

27. The method of 28, wherein retrofitting includes removing a second load coil from said second load coil location.

28. The method of 25, wherein said digital data includes asymmetric digital subscriber loop communications.

29. A method of supporting plain old telephone service voice communications concurrently with asymmetric digital subscriber loop digital data over an asymmetric digital subscriber loop, comprising:
selecting an intermediate point on a two-wire loop connecting a first load coil location to a second load coil location, said intermediate point located between said first load coil location and said second load coil location to extend said two-wire loop by simultaneously supporting a first communication within a voice frequency band and a second communication within an asymmetric digital subscriber loop frequency band higher than said voice frequency band;
providing an extender circuit at said intermediate point, said extender circuit having a first end and a second end, said first end coupled to said first load coil location and said second end coupled to said second load coil location, said first load coil location having a first load coil coupled thereto and said second load coil location having a second load coil coupled thereto, said second load coil including a first leg and a second leg;
modifying said first load coil by short-circuiting said first load coil location with a jumper disposed in a parallel relationship across said first load coil, wherein said extender circuit is closer to said first load coil location than to said second load coil location; and
providing a modified load coil circuit at said second load coil location for modifying said second load coil, said modified load coil circuit including a first shunt network and a second shunt network, said first shunt network including a first shunt capacitor and a first shunt resistor across said first leg of said second load coil, and said second shunt network including a second shunt capacitor and a second shunt resistor across said second leg of said second load coil.

30. The method of claim 29, wherein said first load coil supports said first communication within said voice frequency band and said first shunt network supports said second communication within said asymmetric digital subscriber loop frequency band in a first direction.

31. An apparatus for supporting digital data on a previously deployed transmission medium that supports plain old telephone service voice communications, comprising:
an extender circuit having a first end and a second end, said first end coupled to a first load coil location and said second end coupled to a second load coil location, said second load coil location including a load coil, said load coil having a first leg and a second leg, wherein said extender circuit is located at an intermediate point between said first load coil location and said second load coil location;
a jumper to short-circuit said first load coil location; and
a modified load coil circuit coupled to said second load coil location, said modified load coil circuit including a first circuit portion and a second circuit portion, said first circuit portion including a first shunt capacitor and a first shunt resistor coupled across said first leg of said load coil, and said second circuit portion including a second shunt capacitor and a second shunt resistor coupled across said second leg of said load coil.

32. An apparatus for supporting plain old telephone service voice communications concurrently with asymmetric digital subscriber loop digital data over a long subscriber loop, comprising:
an extender circuit having a first end and a second end, said first end coupled to a first load coil location and said second end coupled to a second load coil location, said first load coil location having a first load coil and said second load coil location having a second load coil, said second load coil having a first leg and a second leg, said extender circuit located at an intermediate point between said first load coil location and said second load coil location, wherein said extender circuit is closer to said first load coil location than to said second load coil location;
a jumper for modifying said first load coil with a short-circuit deployed at said first load coil location in a parallel relationship across said first load coil; and
a modified load coil circuit coupled to said second load coil location for modifying said second load coil, said modified load coil circuit including a first shunt network and a second shunt network, said first shunt network including a first shunt capacitor and a first shunt resistor coupled across said first leg of said second load coil, and said second shunt network including a second shunt capacitor and a second shunt resistor coupled across said second leg of said second load coil.
